(19) United States
(12) Patent Application Publication
(10) Pub. No.: US 2026/0033388 A1
(43) Pub. Date: Jan. 29, 2026

(54) PACKAGING STRUCTURE AND METHODS OF FORMING THE SAME

(71) Applicant: TAIWAN SEMICONDUCTOR MANUFACTURING COMPANY, LTD., Hsinchu (TW)

(72) Inventors: Yun-Fang WU, Hsinchu (TW); Yi Chen HO, Taichung (TW)

(21) Appl. No.: 18/950,293

(22) Filed: Nov. 18, 2024

Related U.S. Application Data
(60) Provisional application No. 63/675,973, filed on Jul. 26, 2024.

(51) Int. Cl. H01L 23/00; H01L 25/16

(52) U.S. Cl. CPC H01L 24/20; H01L 24/19; H01L 24/24; H01L 25/165; H01L 24/32; H01L 24/73; H01L 2224/19; H01L 2224/2101; H01L 2224/2105; H01L 2224/211; H01L 2224/214; H01L 2224/215; H01L 2224/24101; H01L 2224/24137; H01L 2224/24265; H01L 2224/244; H01L 2224/32225; H01L 2224/73267; H01L 2924/30101; H01L 2924/30105; H01L 2924/364; H01L 2924/365

(57) ABSTRACT

A packaging structure and methods of forming the same are described. In some embodiments, the structure includes a semiconductor die and an RDL disposed over the semiconductor die. The RDL includes a first dielectric layer, a second dielectric layer disposed over the first dielectric layer, and a conductive feature. The conductive feature includes a first portion disposed in the first dielectric layer and a second portion disposed in the second dielectric layer. The RDL further includes a first functional layer disposed between the first dielectric layer and the first portion of the conductive feature and a first n-type insulating layer disposed between the first functional layer and the first portion of the conductive feature. The first n-type insulating layer has a higher concentration of negative ions than the first functional layer.

### CROSS-REFERENCE TO RELATED APPLICATIONS

This application claims priority to U.S. Provisional Application Ser. No. 63/675,973 filed Jul. 26, 2024, which is incorporated by reference in its entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for even smaller electronic devices has grown recently, there has grown a need for smaller and more creative packaging techniques of semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 are side views of various stages of manufacturing a packaging structure, in accordance with some embodiments.

FIGS. 6A, 6B, 6C, 6D, 6E, 6F, 6G, 6H, 6I, and 6J are side views of various stages of manufacturing a redistribution layer of the packaging structure, in accordance with some embodiments.

FIGS. 7A and 7B are side views of various stages of manufacturing the redistribution layer of the packaging structure, in accordance with alternative embodiments.

FIGS. 8A, 8B, 8C, 8D, 8E, 8F, 8G, 8H, 8I, and 8J are side views of various stages of manufacturing the redistribution layer of the packaging structure, in accordance with alternative embodiments.

FIGS. 9A, 9B, 9C, and 9D are side views of various stages of manufacturing the redistribution layer of the packaging structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

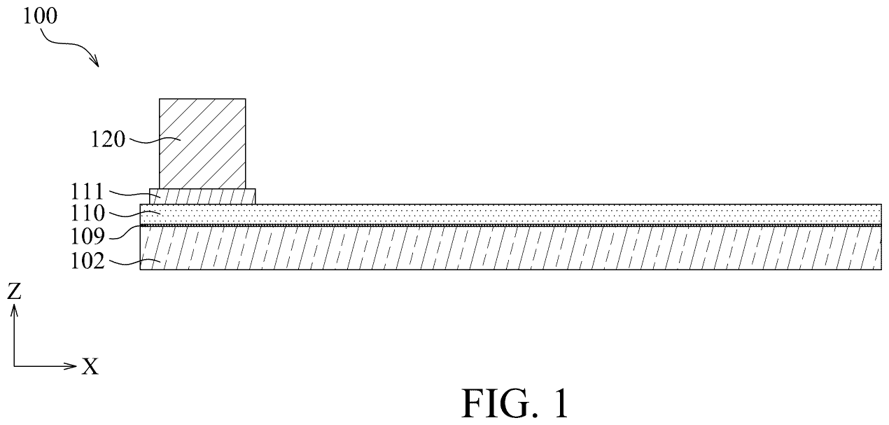

FIGS. 1-5 illustrate various stages of manufacturing a packaging structure 100 in accordance with various embodiments of this disclosure. It is understood that additional operations can be provided before, during, and after processes shown by FIGS. 1-5 and some of the operations described below can be replaced or eliminated, for additional embodiments of the method. The order of the operations/processes may be interchangeable.

FIGS. 1, 2, 3, 4, and 5 are side views of various stages of manufacturing the packaging structure 100, in accordance with some embodiments. As shown in FIG. 1, a buffer layer 110 is formed on a carrier 102. The buffer layer 110 is a dielectric layer, which may be a polymer layer. The polymer layer may include, for example, polyimide, low temperature polybenzoxazole (PBO), benzocyclobutene (BCB), an ajinomoto buildup film (ABF), a solder resist film (SR), or the like. The buffer layer 110 is a substantially planar layer having a substantially uniform thickness, in which the thickness may be greater than about 2 μm, and may be in a range from about 2 μm to about 40 μm. In some embodiments, top and bottom surfaces of the buffer layer 110 are also substantially planar. The carrier 102 may be a blank glass carrier, a blank ceramic carrier, or the like. In some embodiments, an adhesive layer 109 can be formed on the carrier 102, and the buffer layer 110 is formed on the adhesive layer 109. The adhesive layer 109 may be made of an adhesive, such as ultra-violet (UV) glue, light-to-heat conversion (LTHC) glue, or the like, although other types of adhesives may be used.

As shown in FIG. 1, a conductive feature 120 is formed on the buffer layer 110. In some embodiments, a seed layer 111 is formed on the buffer layer 110, and the conductive feature 120 is formed on the seed layer 111. The seed layer 111 may be formed by any suitable process, such as physical vapor deposition (PVD) or metal foil laminating. The seed layer 111 may include copper, copper alloy, aluminum, titanium, titanium alloy, or combinations thereof. In some embodiments, the seed layer 111 includes a titanium layer and a copper layer over the titanium layer. In alternative embodiments, the seed layer 111 is a copper layer.

After the formation of the seed layer 111, a photoresist (not shown) is applied over the seed layer and is then patterned. As a result, an opening (not shown) is formed in the photoresist, through which a portion of the seed layer 111 is exposed. Next, a conductive material is formed in opening of the photoresist through plating, which may be electro plating or electro-less plating. The conductive material is plated on the exposed portion of the seed layer 111. The conductive material may include copper, aluminum, tungsten, nickel, solder, or alloys thereof. In some embodiments, the seed layer 111 and the conductive material include the same material, and the seed layer 111 may be merged with the conductive material with no distinguishable interface therebetween. In some embodiments, the conductive feature 120 is a through via (TV). After the plating of the conductive material, the photoresist is removed, and the resulting conductive feature 120 is shown in FIG. 1. After the photoresist is removed, some portions of the seed layer 111 are exposed. Next, an etch process is performed to remove the exposed portions of seed layer 111, and the etch process may include an anisotropic etching. A portion of the seed layer 111 that is covered by the conductive material, on the other hand, remains not etched. In some embodiments, the conductive feature 120 has a height along the Z direction ranging from about 100 microns to about 250 microns.

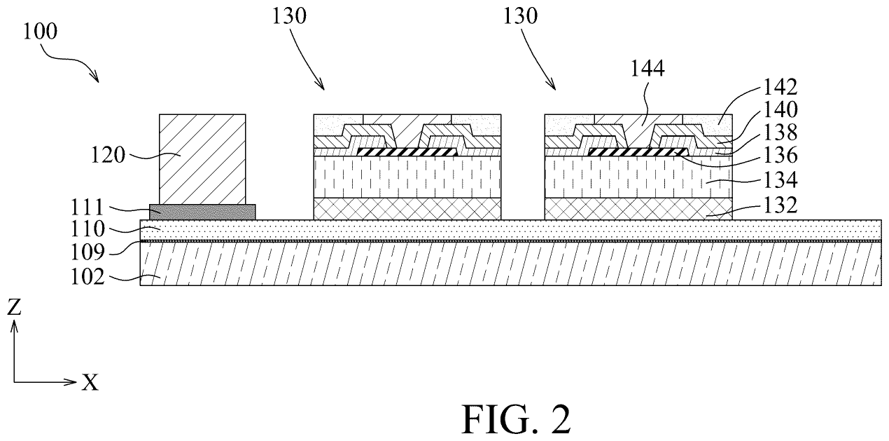

As shown in FIG. 2, one or more semiconductor dies 130, such as one or more system-on-chip (SoC) dies, are attached to the buffer layer 110. In some embodiments, each semiconductor die 130 is attached to the buffer layer 110 through a die-attach film (DAF) 132, which is an adhesive film pre-attached on the semiconductor die 130 before the semiconductor die 130 is placed on buffer layer 110. Each semiconductor die 130 may include a semiconductor substrate 134 having a back surface (the surface facing down) in physical contact with the DAF 132. The semiconductor die 130 may include integrated circuit devices (such as active devices, which include transistors, resistors, capacitors, for example, not shown) at the front surface (the surface facing up) of the semiconductor substrate 134. Since the carrier 102 is at wafer level, although two semiconductor dies 130 are illustrated, a plurality of semiconductor dies 130 is placed over the buffer layer 110, and the semiconductor dies 130 may be allocated as an array including a plurality of rows and a plurality of columns.

In some embodiments, an interconnect structure (not shown) is disposed over the integrated circuit devices. The interconnect structure may include a plurality of conductive features embedded in a dielectric material. The conductive features may be conductive lines and conductive vias. In some embodiments, passive devices, such as capacitors and/or resistors are also embedded in the dielectric material. The dielectric material may be any suitable dielectric material. In some embodiments, the dielectric material includes a plurality of intermetal dielectric (IMD) layers. As shown in FIG. 2, one or more contact pads 136 are disposed over the semiconductor substrate 134, such as over the interconnect structure. The contact pads 136 may include an electrically conductive material, such as a metal, for example aluminum or aluminum-copper. A passivation layer 138 is disposed on the contact pads 136 and over the interconnect structure. The passivation layer 138 may include one or more dielectric layers, such as silicon oxide layers, silicon nitride layers, silicon oxynitride layers, or a combination thereof. A dielectric layer 140 is disposed on the passivation layer 138. The dielectric layer 140 may include any suitable dielectric material. In some embodiments, the dielectric layer 140 is made of or includes a polymer, such as polyimide, polybenzoxazole (PBO), benzocyclobutene (BCB), or the like. The term “polymer” can represent thermosetting polymers, thermoplastic polymers, or any mixtures thereof. Another dielectric layer 142 is disposed on the dielectric layer 140. The dielectric layer 142 may include any suitable dielectric material. In some embodiments, the dielectric layer 142 is made of or includes a polymer, such as polyimide, PBO, BCB, or the like. One or more conductive features 144 are disposed in the dielectric layer 142. In some embodiments, the conductive features 144 extend through the dielectric layer 140 and the passivation layer 138 and are in electrical contact with the contact pads 136. The conductive feature 144 may include an electrically conductive material, such as a metal, for example copper. In some embodiments, the top surfaces of the conductive features 144 and the top surface of the dielectric layer 142 are substantially coplanar, as shown in FIG. 2.

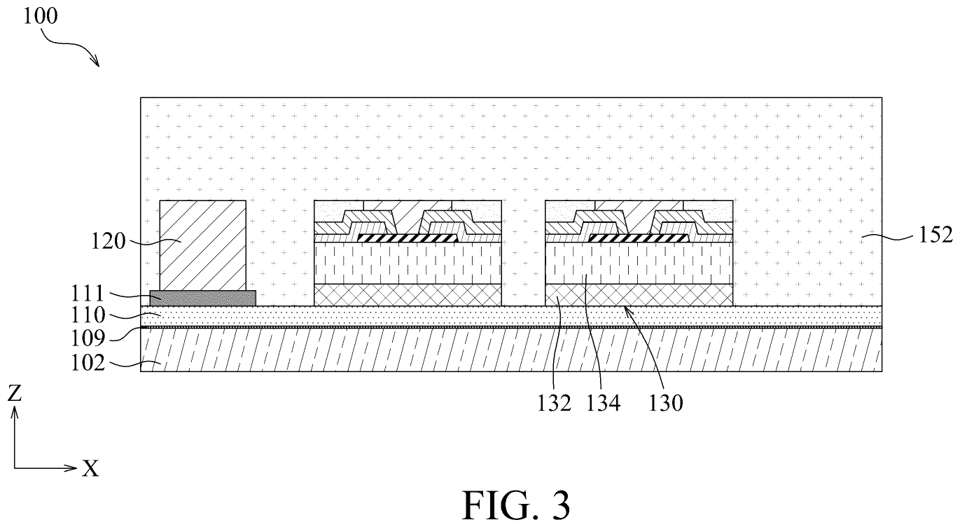

As shown in FIG. 3, a molding material 152 (or molding compound) is formed to encapsulate the conductive feature 120 and the semiconductor dies 130. In some embodiments, the molding material 152 includes a polymer-based material. The polymer-based material can include, for example, plastic materials, epoxy resin, polyimide, polyethylene terephthalate (PET), polyvinyl chloride (PVC), polymethylmethacrylate (PMMA), polymer components doped with fillers including fiber, clay, ceramic, inorganic particles, or any combinations thereof. In some embodiments, the molding material is a polymer. Next, the molding material 152 is cured by a curing process, in some embodiments. The curing process may include heating the molding material 152 to a predetermined temperature for a predetermined period of time, using an anneal process or other heating process. The curing process may also include an ultra-violet (UV) light exposure process, an infrared (IR) energy exposure process, combinations thereof, or a combination thereof with a heating process. Alternatively, the molding material 152 may be cured using other methods.

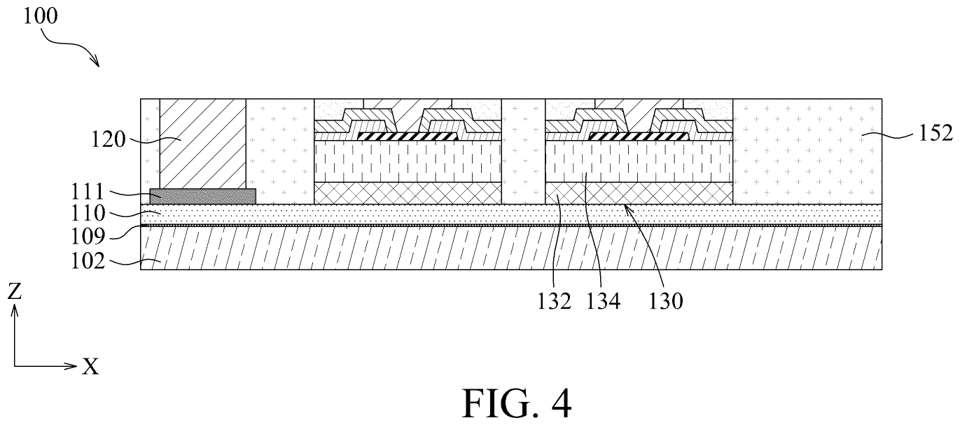

As shown in FIG. 4, a grinding process or a planarization process is performed to remove the portion of the molding material 152 disposed over the semiconductor dies 130 and the conductive feature 120. As a result, in some embodiments, the top surfaces of the semiconductor dies 130, the conductive feature 120, and the molding material 152 are substantially coplanar.

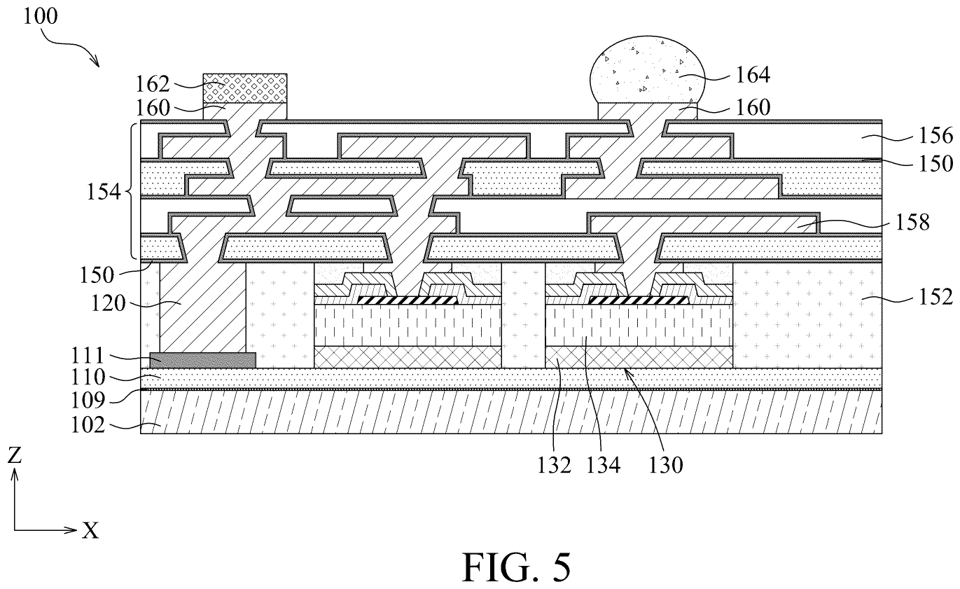

As shown in FIG. 5, a redistribution layer (RDL) 154 is formed on the molding material 152, the conductive feature 120, and the semiconductor dies 130. In some embodiments, the RDL 154 is a structure including a plurality of dielectric layers 156 and a plurality of conductive features 158 embedded in the plurality of dielectric layers, as shown in FIG. 5. The dielectric layer 156 includes any suitable dielectric material, such as silicon nitride, silicon oxide, or the like, or a polymer, such as PBO, polyimide, or the like. The dielectric layer 156 may be formed by any suitable method, such as CVD, ALD, PECVD, FCVD, or other applicable deposition methods. The conductive features 158 may include an electrically conductive material, such as a metal. In some embodiments, the conductive feature 158 is made of or includes copper. The conductive features 158 may be electrically connected to the conductive feature 120 and the semiconductor dies 130.

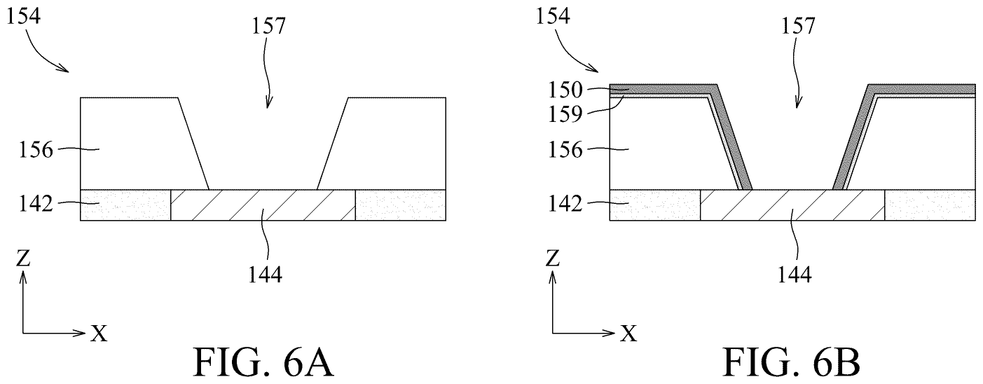

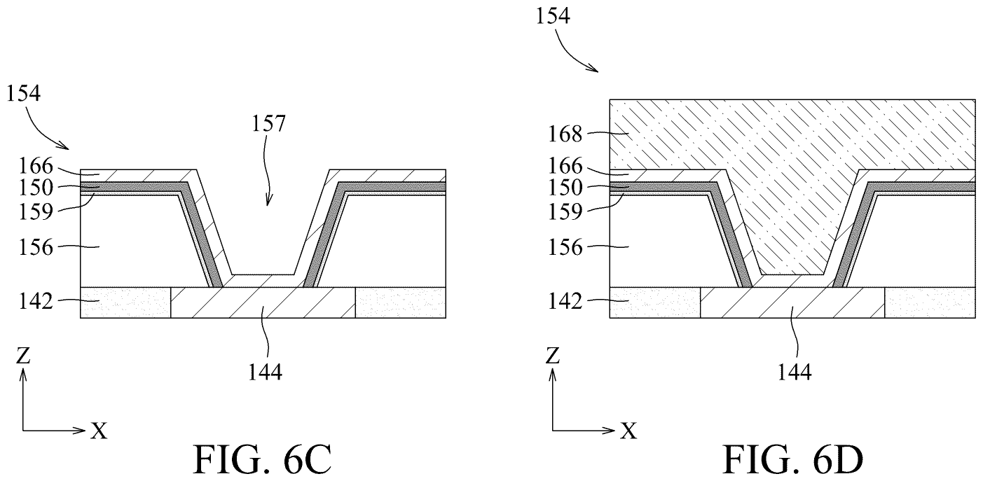

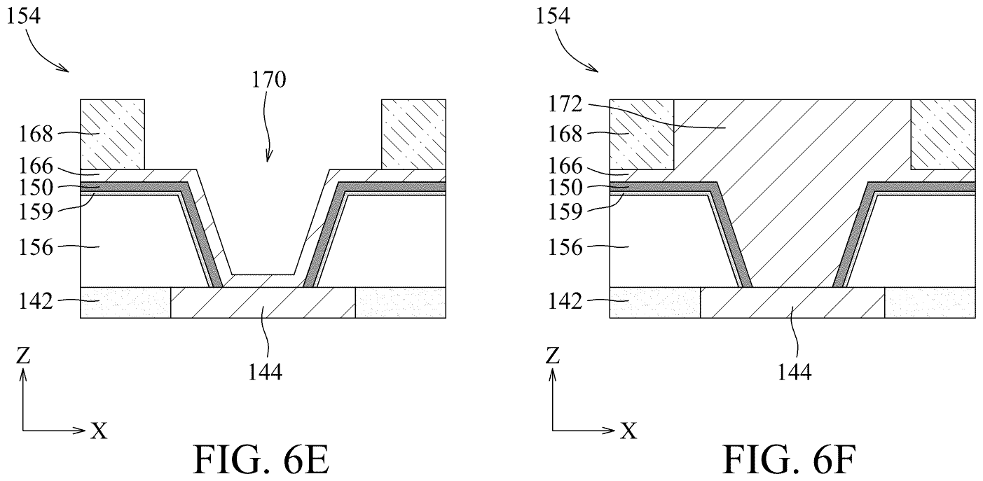

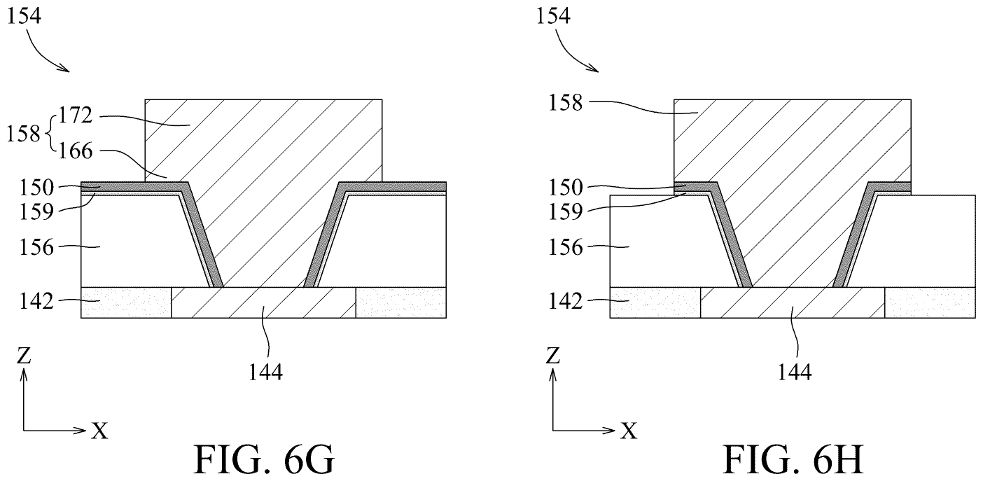

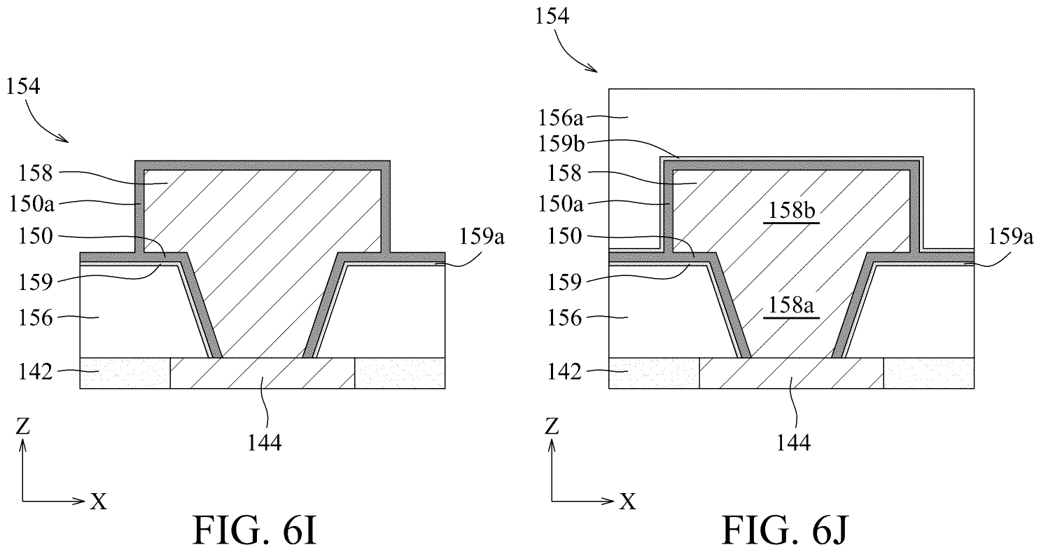

In some embodiments, the dielectric layer 156 is thicker than at least one IMD layer of the plurality of IMD layers of the interconnect structure. For example, the dielectric layer 156 may have a thickness greater than 1 micron, such as from about 4 microns to about 10 microns. In some embodiments, the thickness of the dielectric layer 156 increases in a direction away from the semiconductor dies 130. For example, the bottom dielectric layer 156 has a thickness ranging from about 3 microns to about 7 microns, the dielectric layer 156 disposed thereover has a thickness ranging from about 5 microns to about 9 microns, the dielectric layer 156 disposed thereover has a thickness ranging from about 5 microns to about 9 microns, and the top dielectric layer 156 has a thickness ranging from about 6 microns to about 10 microns. Similarly, the thickness of the conductive feature 158 is substantially greater than the thickness of the conductive features embedded in the interconnect structure. In some embodiments, the conductive feature 158 includes a first portion 158a and a second portion 158b (FIG. 6J), and the thickness of the second portion 158b of the conductive features 158 may be greater than about 2 microns, such as from about 3 microns to about 6 microns. The dimensions of the conductive features 158 are also substantially greater than those of the conductive features of the interconnect structure. For example, the length of the second portion 158b of the conductive feature 158 along the X direction may be greater than about 10 microns, which may be 100 to 1000 times the length of the conductive feature of the interconnect structure.

In some embodiments, one or more under-bump metallurgies (UBMs) 160 are formed on top of the RDL 154, as shown in FIG. 5. The UBMs 160 may be formed of an electrically conductive material, such as nickel, copper, titanium, or multi-layers thereof. In accordance with some exemplary embodiments, the UBMs 160 include a titanium layer and a copper layer over the titanium layer. The UBM 160 has a thickness along the Z direction ranging from about 5 microns to about 10 microns.

As shown in FIG. 5, an integrated passive device (IPD) 162 and a connector 164 are electrically connected to the UBMs 160. The IPD 162 may be a capacitor, a resistor, an inductor or the like, or a combination thereof. The connector 164 may be referred to as a conductive terminal. In some embodiments, the connector 164 is, for example, a solder ball or a ball grid array (BGA) ball. In some embodiments, the material of the connector 164 includes copper, aluminum, lead-free alloys (e.g., gold, tin, silver, aluminum, or copper alloys) or lead alloys (e.g., lead-tin alloys). The connector 164 has a thickness along the Z direction ranging from about 80 microns to about 180 microns.

In some embodiments, as shown in FIG. 5, the packaging structure 100 includes a functional layer 150. The functional layer 150 may be disposed between the conductive features 158 and the dielectric layers 156 in order to reduce electromigration between the conductive features 158 and the dielectric layers 156. In some embodiments, the conductive features 158 includes copper, the dielectric layers 156 includes polyimide, and the copper may leak into the polyimide, which may lead to time-dependent dielectric breakdown (TDDB). By forming the functional layer 150 between the conductive features 158 and the dielectric layers 156, the electromigration of the metal from the conductive features 158 to the polyimide of the dielectric layers 156 is reduced or eliminated.

In some embodiments, the functional layer 150 is a nitride, such as aluminum nitride (AlN) or TiAlN. The functional layer 150 may be formed on the dielectric layer 156 or the dielectric layer 156 may be formed on the functional layer 150. The bonding between the functional layer 150 and the dielectric layer 156 forms an n-type insulating layer 159 (FIG. 6B) at the interface between the functional layer 150 and the dielectric layer 156 to prevent metal components of the conductive feature 158 from leaking into the dielectric layer 156 due to electromigration. The nitrogen in the functional layer 150 reacts with the dielectric layer 156 to form NH⁻ at the interface, which is part of the n-type insulating layer 159. For example, the n-type insulating layer 159 may be a portion of the functional layer 150 having a higher concentration of NH⁻ ions at the interface between the functional layer 150 and the dielectric layer 156. The n-type insulating layer 159 including higher concentration of the negative ions prevents electromigration and current leakage by electric repulsion.

The functional layer 150 is formed by any suitable process. In some embodiments, a plasma process, such as a plasma enhanced chemical vapor deposition (PECVD) process, is performed to form the functional layer 150. The PECVD process may include using a plasma with one or more nitrogen-containing gases, such as N₂, NH₃, or N₂O. In some embodiments, the thickness of the functional layer 150 may range from about 20 angstroms to about 50 angstroms. If the thickness of the functional layer 150 is less than about 20 angstroms, the functional layer 150 may not be sufficient to prevent electromigration. On the other hand, if the thickness of the functional layer 150 is greater than about 50 angstroms, the electrical resistance is unnecessarily reduced. In some embodiments, a ratio of the thickness of the second portion 158b (FIG. 6J) of the conductive feature 158 to the thickness of the functional layer 150 is greater than about 500, such as from about 800 to about 2500. If the ratio of the thickness of the second portion 158b of the conductive feature 158 to the thickness of the functional layer 150 is less than about 800, such as less than about 500, the electrical resistance of the conductive feature 158 is too high. Similarly, in some embodiments, the ratio of the thickness of the dielectric layer 156 to the thickness of the functional layer 150 is greater than about 800, such as from about 1000 to about 4000. If the ratio of the thickness of the dielectric layer 156 to the thickness of the functional layer 150 is less than about 800, such as less than about 500, the parasitic capacitance of the RDL 154 may be high, because the functional layer 150 has a higher k value compared to the dielectric layer 156. In some embodiments, the functional layer 150 is a conformal layer. The term “conformal” may be used herein for ease of description upon a layer having substantial same thickness over various regions. In some embodiments, the functional layer 150 is a non-conformal layer having varied thickness.

Subsequent processes may include removing the carrier 102, bonding the semiconductor dies 130 to a semiconductor die to form three-dimensional devices, and separating the three-dimensional devices.

FIGS. 6A, 6B, 6C, 6D, 6E, 6F, 6G, 6H, 6I, and 6J are side views of various stages of manufacturing the RDL 154 of the packaging structure 100, in accordance with some embodiments. As shown in FIG. 6A, in some embodiments, the dielectric layer 156 is deposited over the dielectric layer 142 of the semiconductor die 130 (FIG. 2), and an opening 157 is formed in the dielectric layer 156. The dielectric layer 156 may be formed by any suitable method, such as CVD, ALD, PECVD, FCVD, or other applicable deposition methods. In some embodiments, a curing process is performed after the deposition of the dielectric layer 156 to cure the as-deposited dielectric layer 156. The opening 157 may be formed by any suitable process, such as a dry etch process. A conductive feature, such as the conductive feature 144 (FIG. 2) is exposed in the opening 157, as shown in FIG. 6A. In some embodiments, a sidewall of the dielectric layer 156 forms an angle with respect to the top surface of the conductive feature 144, and the angle ranges from about 80 degrees to about 87 degrees.

As shown in FIG. 6B, the functional layer 150 is selectively formed on the dielectric material of the dielectric layer 156. In some embodiments, a blocking layer (not shown) is selectively formed on the exposed conductive feature 144, and the blocking layer prevents the functional layer 150 from forming on the exposed conductive feature 144. The blocking layer may include a self-assembled monolayer (SAM), which has a head group and a tail group connected to each other. The head group shows a specific affinity for the material of the conductive feature 144, thus the head group is adsorbed onto the top surface of the conductive feature 144. In some embodiments, the head group includes a silane group, a phosphonate group, an amine group, a thiol group, a disulfide group, a carboxyl group, the like, or a combination thereof. The tail group may include an alkyl chain, such as a linear alkyl chain or a branched alkyl chain. In some embodiments, the blocking layer includes n-alkanethiols (e.g., dodecanethiol, octadecanethiol (ODT), or the like), aromatic thiols (e.g., benzenethiol), phosphonic acid (e.g., octadecylphosphonic acid (ODPA)), n-alkanoic acid (e.g., acetic acid), the like, or a combination thereof. The blocking layer is selectively deposited on the conductive feature 144, and not on the dielectric layer 156 due to the specific affinity of the head group of the blocking layer to the material of the conductive feature 144. During the deposition of the functional layer 150, the tail group inhibits the adsorption of the precursors of the functional layer 150. Thus, the functional layer 150 is not formed on the blocking layer. The blocking layer is removed after the formation of the functional layer 150. The removal of the blocking layer may be a selective etch process that does not substantially affect the functional layer 150.

In some embodiments, the functional layer 150 is deposited on the exposed conductive feature 144, and a patterning process is performed to expose the portion of the functional layer 150 formed on the conductive feature 144, while other portions of the functional layer 150 are covered under a mask layer (not shown). The exposed portion of the functional layer 150 is then removed by any suitable process, such as a dry etch process, a wet etch process, or a combination thereof. The mask layer is removed after the removal of the portion of the functional layer 150.

In some embodiments, as shown in FIG. 6B, the bonding of the functional layer 150 and the dielectric layer 156 forms the n-type insulating layer 159, which includes higher concentration of negative ions compared to the functional layer 150 and the dielectric layer 156. The n-type insulating layer 159 may be a portion of the functional layer 150 at the interface between the functional layer 150 and the dielectric layer 156. As described above, the negative ions in the n-type insulating layer 159 prevent electromigration of metal components from the subsequently formed conductive feature 158 into the dielectric layer 156 by electric repulsing.

In some embodiments, the functional layer 150 forms an angle with respect to the top surface of the conductive feature 144, and the angle also ranges from about 80 degrees to about 87 degrees, because the functional layer 150 is formed on the sidewall of the dielectric layer 156.

As shown in FIG. 6C, a seed layer 166 is deposited on the functional layer 150 and the exposed conductive feature 144. The seed layer 166 may include a conductive material, such as a metal. In some embodiments, the seed layer 166 is made of or includes copper. The seed layer 166 may be deposited by any suitable process. In some embodiments, the seed layer 166 is deposited by a physical vapor deposition (PVD) process. Next, as shown in FIG. 6D, a mask layer 168 is deposited on the seed layer 166 and fills the opening 157. The mask layer 168 may be a photoresist layer. As shown in FIG. 6E, an opening 170 is formed in the mask layer 168. The opening 170 may include the opening 157, and a portion of the seed layer 166 formed over the dielectric layer 156 is also exposed in the opening 170. Next, as shown in FIG. 6F, a bulk fill 172 is deposited on the exposed portion of the seed layer 166 in the opening 170. The bulk fill 172 may include any electrically conductive material, such as a metal. In some embodiments, the bulk fill 172 includes the same material as the seed layer 166. In some embodiments, the seed layer 166 and the bulk fill 172 both include copper. The bulk fill 172 may be deposited by any suitable process, such as PVD or electro-chemical plating (ECP). In some embodiments, the bulk fill 172 is also deposited on the mask layer 168, and a planarization process, such as a chemical mechanical polishing (CMP) process, may be performed to remove the portion of the bulk fill 172 formed on the mask layer 168.

As shown in FIG. 6G, the mask layer 168 is removed to expose portions of the seed layer 166, and the exposed portions of the seed layer 166 are then removed. The mask layer 168 may be removed by any suitable process, such as a plasma ash process. After the removal of the mask layer 168, another mask layer (not shown) may be formed on the bulk fill 172, and the exposed portions of the seed layer 166 are removed by a selective etch process. The selective etch process may be an anisotropic process. The selective etch process removes the exposed portions of the seed layer 166 but not the mask layer and the functional layer 150. The edges of the remaining seed layer 166 be substantially flush with corresponding edges of the bulk fill 172, as shown in FIG. 6G. The remaining seed layer 166 and the bulk fill 172 together form the conductive feature 158. In some embodiments, the mask layer used to protect the bulk fill 172 during the removal of the exposed portions of the seed layer 166 may be removed after the removal of the exposed portions of the seed layer 166. In some embodiments, the mask layer used to protect the bulk fill 172 during the removal of the exposed portions of the seed layer 166 may remain on the bulk fill 172 after the removal of the exposed portions of the seed layer 166.

As shown in FIG. 6H, in some embodiments, after the removal of the portions of the seed layer 166, the exposed portions of the functional layer 150 and the portions of the n-type insulating layer 159 disposed therebelow are removed. The portions of the functional layer 150 and the n-type insulating layer 159 may be removed by any suitable process, such as a dry etch process, a wet etch process, or a combination thereof. In some embodiments, the mask layer used to protect the bulk fill 172 is removed after the removal of the portions of the seed layer 166, and a selective etch process is performed to remove the portions of the functional layer 150 and the n-type insulating layer 159. The selective etch process does not substantially affect the bulk fill 172. In some embodiments, the mask layer used to protect the bulk fill 172 remains on the bulk fill 172 after the removal of the portions of the seed layer 166, and the mask layer protects the bulk fill 172 during the removal of the portions of the functional layer 166 and the n-type insulating layer 159. In some embodiments, the edges of the remaining functional layer 150 are substantially flush with corresponding edges of the conductive feature 158, as shown in FIG. 6H.

As shown in FIG. 6I, another functional layer 150a is deposited on the dielectric layer 156 and around the conductive feature 158. Similarly, another n-type insulating layer 159a is formed between the newly deposited functional layer 150a and the dielectric layer 156. In some embodiments, the functional layer 150a includes the same material as the functional layer 150 and is formed by the same process as the functional layer 150. In some embodiments, the n-type insulating layer 159a includes the same material as the n-type insulating layer 159 and is formed by the same process as the n-type insulating layer 159. Next, as shown in FIG. 6J, another dielectric layer 156a is deposited on the functional layer 150a and over the conductive feature 158. The bonding of the newly deposited dielectric layer 156a and the functional layer 150a creates an n-type insulating layer 159b, as shown in FIG. 6J. In some embodiments, the dielectric layer 156a includes the same material as the dielectric layer 156 and is formed by the same process as the dielectric layer 156. In some embodiments, the n-type insulating layer 159b includes the same material as the n-type insulating layer 159 and is formed by the same process as the n-type insulating layer 159.

As shown in FIG. 6J, the conductive feature 158 includes a first portion 158a disposed in the dielectric layer 156 and a second portion 158b disposed in the dielectric layer 156a. In some embodiments, the first portion 158a of the conductive feature 158 is a conductive via, and the second portion 158b of the conductive feature 158 is a conductive line. In some embodiments, the first portion 158a of the conductive feature 158 is surrounded by the n-type insulating layer 159, which is formed as a result of the bonding of the functional layer 150 and the dielectric layer 156. The second portion 158b of the conductive feature 158 is surrounded by the n-type insulating layer 159b, which is formed as a result of the bonding of the functional layer 150a and the dielectric layer 156a. The n-type insulating layers 159, 159b prevent metal components in the conductive feature 158 from leaking into the dielectric layers 156, 156a by blocking electromigration. As a result, TDDB is improved.

In some embodiments, the functional layer 150a disposed on the second portion 158b of the conductive feature 158 may also function as an etch stop layer. Subsequent processes may include forming an opening in the dielectric layer 156a and repeating the processes described in FIGS. 6A-6J. The functional layer 150a protects the second portion 158b of the conductive feature 158 during the formation of the opening in the dielectric layer 156a.

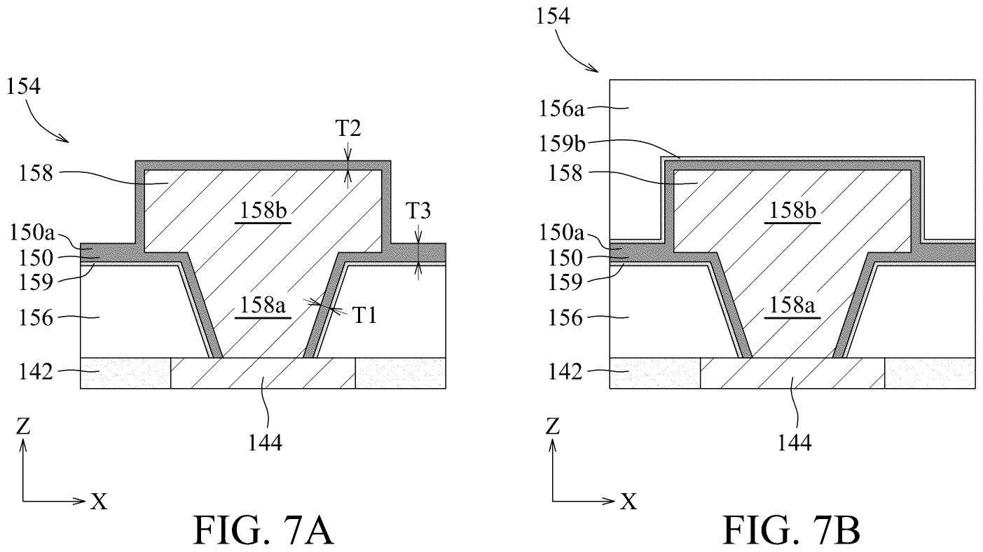

FIGS. 7A and 7B are side views of various stages of manufacturing the RDL 154 of the packaging structure 100, in accordance with alternative embodiments. In some embodiments, as shown in FIG. 7A, after the removal of the exposed portions of the seed layer 166 (FIG. 6G), the exposed portions of the functional layer 150 are not removed. The functional layer 150a is then deposited on the functional layer 150 and around the second portion 158b of the conductive feature 158. In such embodiment, the n-type insulating layer 159a is not formed, because the functional layer 150a is not formed on the dielectric layer 156. In some embodiments, the functional layer 150 has a thickness T1, the functional layer 150a has a thickness T2, and the portions of the functional layer 150 and the functional layer 150a located on the dielectric layer 156 has a combined thickness T3 substantially greater than the thickness T1 or the thickness T2. In some embodiments, the thickness T1 is substantially the same as the thickness T2, and the thickness T3 is about twice the thickness T1 or the thickness T2.

Next, as shown in FIG. 7B, the dielectric layer 156a is deposited on the functional layer 150a, and the n-type insulating layer 159b is formed between the dielectric layer 156a and the functional layer 150a. Compared to the processes described in FIGS. 6H-6J, the processes described in FIGS. 7A and 7B have less steps (without removing the exposed portions of the functional layer 150 and the portions of the n-type insulating layer 159 disposed therebelow. However, the parasitic capacitance of the RDL 154 may be slightly higher due to the combination of the functional layers 150, 150a located between the dielectric layer 156 and the dielectric layer 156a. Similar to the structure shown in FIG. 6J, the first portion 158a of the conductive feature 158 is surrounded by the n-type insulating layer 159, and the second portion 158b of the conductive feature 158 is surrounded by the n-type insulating layer 159b. As a result, electromigration of the metal components from the conductive feature 158 to the dielectric layers 156, 156b is blocked.

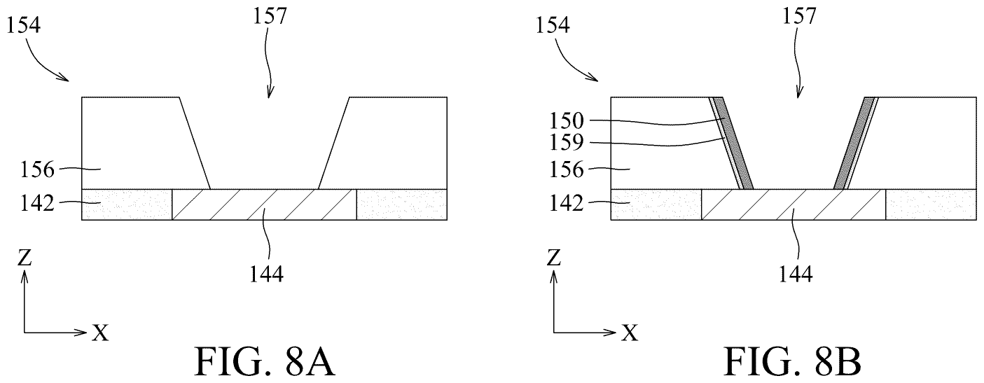

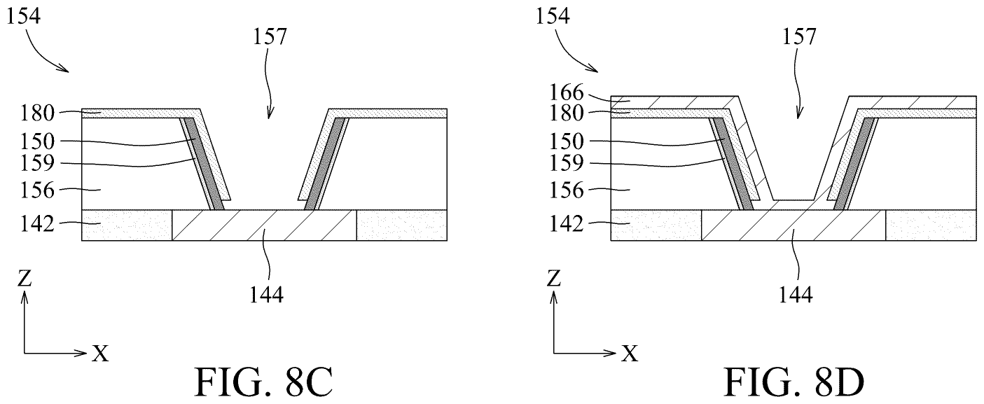

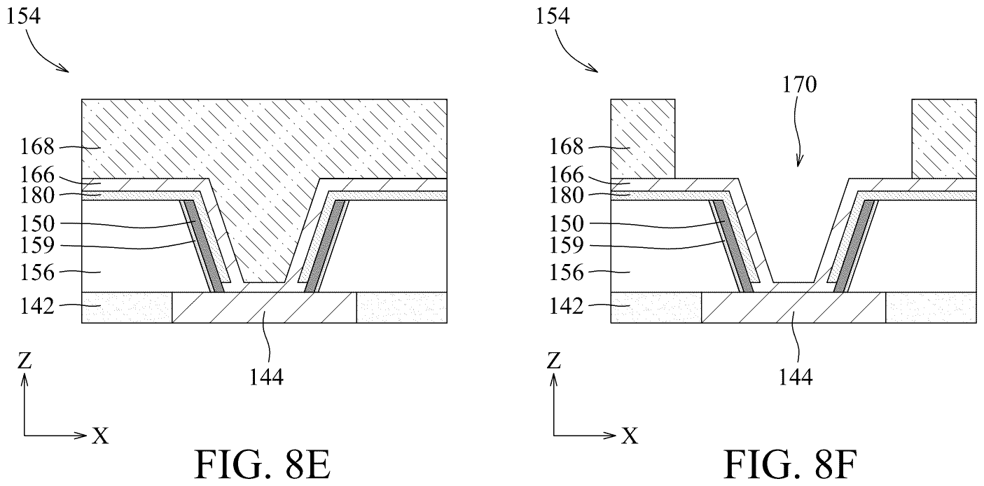

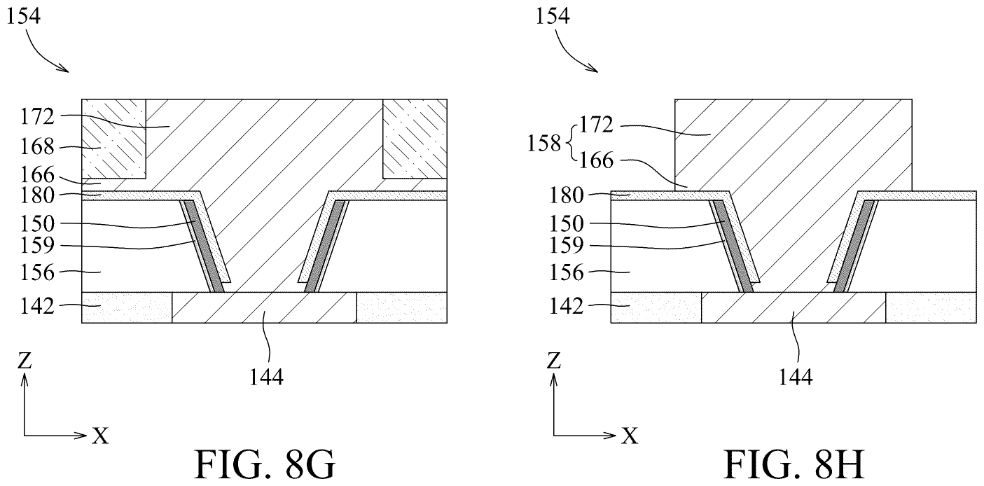

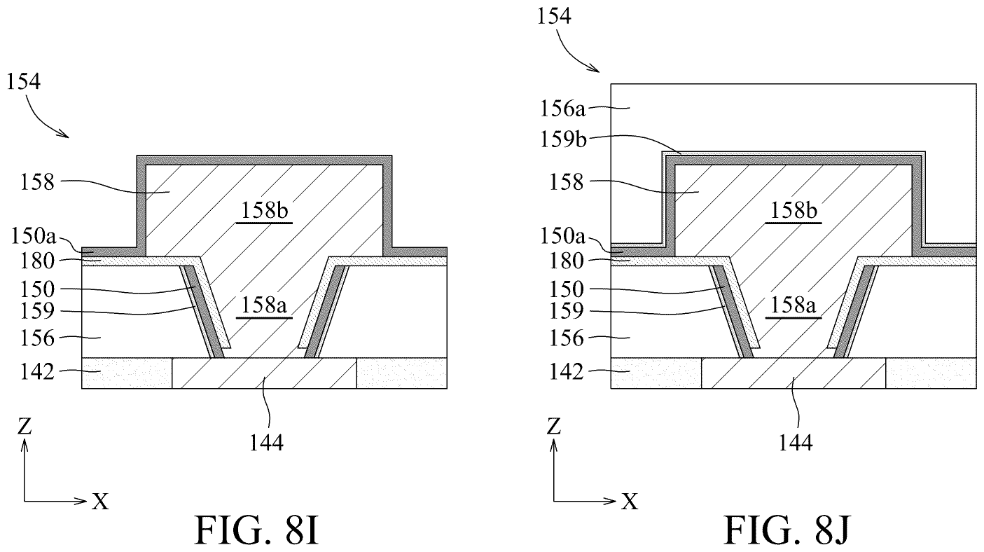

FIGS. 8A, 8B, 8C, 8D, 8E, 8F, 8G, 8H, 8I, and 8J are side views of various stages of manufacturing the RDL 154 of the packaging structure 100, in accordance with alternative embodiments. As shown in FIG. 8A, the opening 157 is formed in the dielectric layer 156 to expose the conductive feature 144. The intermediate structure shown in FIG. 8A may be the same as the intermediate structure shown in FIG. 6A. Next, as shown in FIG. 8B, the functional layer 150 is formed on the sidewall of the dielectric layer 156 in the opening 157. As a result, the n-type insulating layer 159 is formed between the functional layer 150 and the dielectric layer 156. The functional layer 150 is formed on the sidewall of the dielectric layer 156 by any suitable process. In some embodiments, a blocking layer, such as the blocking layer described in FIG. 6B, is selectively formed on the conductive feature 144, and the functional layer 150 is formed on the dielectric layer 156 (similar to the structure shown in FIG. 6B). Next, a sacrificial layer (not shown) may be formed on the functional layer 150 and the conductive feature 144, and the sacrificial layer fills the opening 157. The sacrificial layer may be a bottom anti-reflective coating (BARC) layer. The sacrificial layer may be also formed over the dielectric layer 156. Then, a planarization process, such as a CMP process, may be performed to remove the portion of the sacrificial layer formed over the dielectric layer 156. The CMP process may also remove the portions of the functional layer 150 disposed over the dielectric layer 156. In other words, after the CMP process, the top surface of the dielectric layer 156 is exposed. The remaining sacrificial layer disposed in the opening 157 may be removed by any suitable process. In some embodiments, a selective etch process may be used to remove the sacrificial layer, while other components of the RDL 154 are not affected. In some embodiments, as shown in FIG. 8B, a top surface of the dielectric layer 156 and a top surface of the functional layer 150 are substantially coplanar.

As shown in FIG. 8C, an adhesion layer 180 is selectively deposited on the dielectric layer 156 and the functional layer 150. The adhesion layer 180 is not deposited on the conductive feature 144. In some embodiments, a blocking layer (not shown) is formed on the conductive feature 144 to inhibit the formation of the adhesion layer 180 on the conductive feature 144. The blocking layer may be the same blocking layer described in FIG. 6B. After the removal of the blocking layer, a gap may be formed between the adhesion layer 180 and the conductive feature 144. The adhesion layer 180 may include any material that enhances the adhesion of the functional layer 150 to the dielectric layer 156. In some embodiments, the dielectric layer 156 includes polyimide, the functional layer 150 includes AlN, and the adhesion layer 180 includes beta-Si₃N₄. Because both the AlN and beta-Si₃N₄ have hexagonal structures, AlN can adhere better on beta-Si₃N₄ than on polyimide. In some embodiments, compared to the polyimide, beta-Si₃N₄ improves lattice match with AlN by about 41 percent. Other materials having the hexagonal structures may be used as the adhesion layer 180. In some embodiments, GaN is used as the adhesion layer 180. In some embodiments, the material of the adhesion layer 180 may have a crystallization rate greater than about 50 percent. In other words, less than 50 percent of the adhesion layer 180 is amorphous, while greater than 50 percent of the adhesion layer 180 is crystalline. In some embodiments, the material of the adhesion layer 180 has a lattice constant ranging from about 2 angstroms to about 10 angstroms. The adhesion layer 180 increases de-bond energy of the functional layer 150, which enhances the adhesion of the functional layer 150 to the dielectric layer 156.

In some embodiments, the adhesion layer 180 has a thickness ranging from about 1.5 angstroms to about 50 angstroms. If the thickness of the adhesion layer 180 is less than about 1.5 angstroms, the adhesion layer 180 is not sufficient to improve the adhesion of the functional layer 150 to the dielectric layer 156. On the other hand, if the thickness of the adhesion layer 180 is greater than about 50 angstroms, parasitic capacitance is increased because the k value of the adhesion layer is greater than the k value of the dielectric layer 156. The adhesion layer 180 may be deposited by any suitable process, such as PECVD, APCVD, LPCVD, UHCVD, AACVD, DLICVD, MPCVD, RPECVD, ALCVD, HWCVD, HPCVD, or RTCVD. In some embodiments, the adhesion layer 180 is a conformal layer.

In some embodiments, the thickness of the functional layer 150 is greater than the thickness of the adhesion layer 180. In some embodiments, the ratio of the thickness of the functional layer 150 to the thickness of the adhesion layer 180 ranges from about 1 to about 15.

As shown in FIG. 8D, the seed layer 166 is deposited on the adhesion layer 180 and the conductive feature 144. In some embodiments, the seed layer 166 fills the gap between the adhesion layer 180 and the conductive feature 144, as shown in FIG. 8D. Next, the mask layer 168 is deposited on the seed layer 166 and fills the opening 157, as shown in FIG. 8E. Then, the opening 170 is formed in the mask layer 168 to expose a portion of the seed layer 166, as shown in FIG. 8F. The bulk fill 172 is formed in the opening 170, as shown in FIG. 8G. The mask layer 168 is removed, and the exposed portions of the seed layer 166 are removed, as shown in FIG. 8H. As described above, another mask layer (not shown) may be first formed on the bulk fill 172 to protect the bulk fill 172 during the removal of the exposed portions of the seed layer 166. As a result, the edges of the remaining seed layer 166 are substantially flush with corresponding edges of the bulk fill 172, as shown in FIG. 8H. The remaining seed layer 166 and the bulk fill 172 together form the conductive feature 158. After the removal of the exposed portions of the seed layer 166, portions of the adhesion layer 180 are exposed, as shown in FIG. 8H.

As shown in FIG. 8I, the functional layer 150a is deposited on the adhesion layer 180 and around the second portion 158b of the conductive feature 158. The functional layer 150a adheres to the adhesion layer 180 better than the dielectric layer 156. By forming the adhesion layer 180 between the dielectric layer 156 and the functional layer 150, the risk of peeling of the functional layer 150a is reduced. Next, as shown in FIG. 8J, the dielectric layer 156a is deposited on the functional layer 150a, and the n-type insulating layer 159b is formed between the dielectric layer 156a and the functional layer 150a.

In some embodiments, the functional layer 150a is a continuous layer and includes a first portion in contact with the adhesion layer 180 and a second portion in contact with the second portion 158b of the conductive feature 158. The first portion of the functional layer 150a is adhered to the adhesion layer 180, and the risk of peeling off of the functional layer 150a is reduced. The second portion of the functional layer 150a is also exposed to the dielectric layer 156a, and the n-type insulating layer 159b is formed as a result. Thus, the second portion of the functional layer 150a forms the n-type insulating layer 159b, which prevents electromigration and current leakage of the metal components of the second portion 158b of the conductive feature 158 to the dielectric layer 156a by electric repulsion. In some embodiments, the functional layer 150 is not formed on the adhesion layer 180. However, because the functional layer 150 is disposed in an opening, and the opening is filled with the conductive feature 158, the risk of peeling of the functional layer 150 is low.

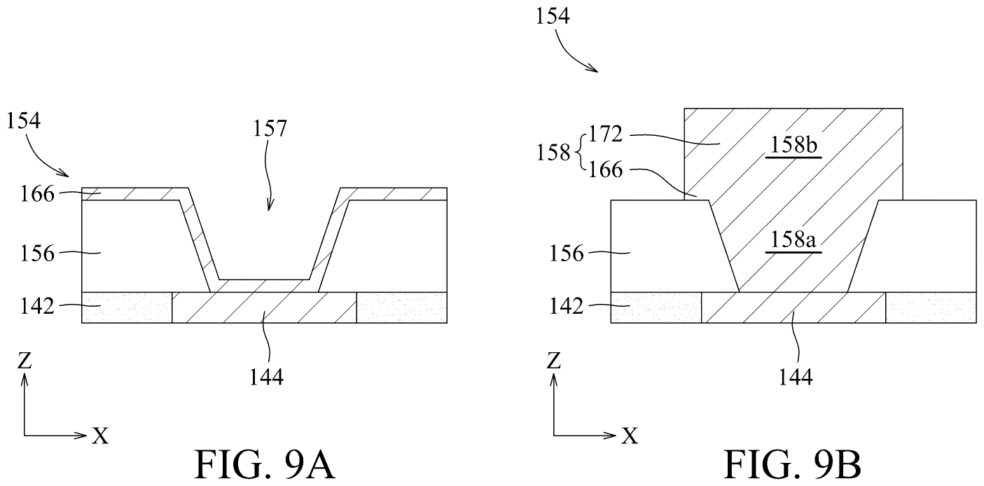

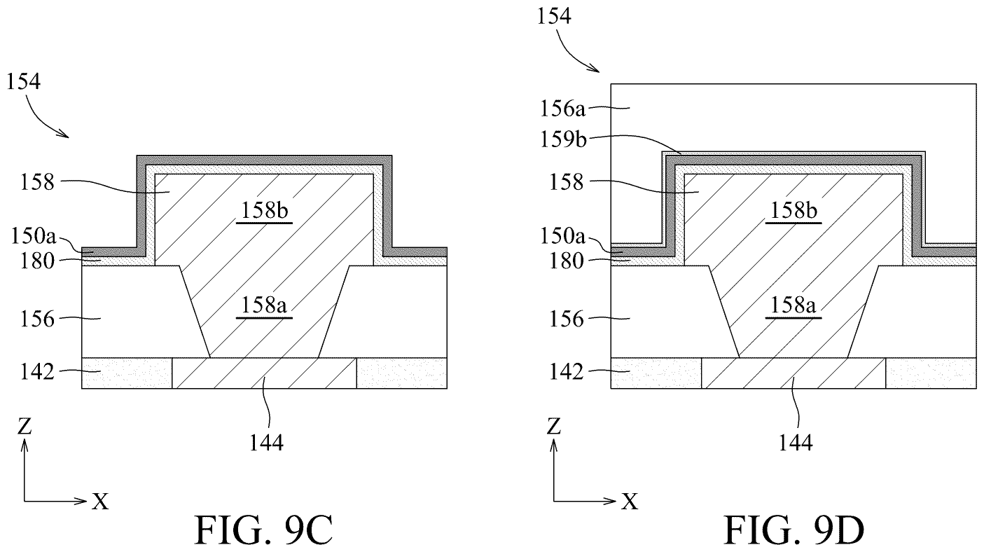

FIGS. 9A, 9B, 9C, and 9D are side views of various stages of manufacturing the RDL 154 of the packaging structure 100, in accordance with alternative embodiments. In some embodiments, as shown in FIG. 9A, the opening 157 is formed in the dielectric layer 156 to expose the conductive feature 144, and the seed layer 166 is deposited on the dielectric layer 156 and the conductive feature 144. In such embodiment, the functional layer 150 and/or the adhesion layer 180 are not formed in the opening 157. Next, as shown in FIG. 9B, the bulk fill 172 is formed on the seed layer 166, and the portions of the seed layer 166 are removed. The bulk fill 172 may be formed by the same processes described in FIGS. 6D-6G.

As shown in FIG. 9C, the adhesion layer 180 is deposited on the dielectric layer 156 and around the conductive feature 158, and the functional layer 150a is deposited on the adhesion layer 180. As described above, the adhesion layer 180 improves the adhesion of the functional layer 150a. Next, as shown in FIG. 9D, the dielectric layer 156a is deposited on the functional layer 150a, and the n-type insulating layer 159b is formed between the dielectric layer 156a and the functional layer 150a. Similar to the functional layer 150a described in FIG. 8J, the functional layer 150a is a continuous layer and includes a first portion disposed over the dielectric layer 156 and a second portion surrounding the second portion 158b of the conductive feature 158. The first portion of the functional layer 150a is adhered to the adhesion layer 180, and the risk of peeling off of the functional layer 150a is reduced. The second portion of the functional layer 150a is also exposed to the dielectric layer 156a, and the n-type insulating layer 159b is formed as a result. Thus, the second portion of the functional layer 150a forms the n-type insulating layer 159b, which prevents electromigration and current leakage of the metal components of the second portion 158b of the conductive feature 158 to the dielectric layer 156a by electric repulsion.

The present disclosure in various embodiments provides a packaging structure 100 including a functional layer 150 bonding with a dielectric layer 156 to form an n-type insulating layer 159 to block electromigration in an RDL 154. In some embodiments, an adhesion layer 180 may be formed between the dielectric layer 156 and the functional layer 150 to enhance the adhesion of the functional layer 150. Some embodiments may achieve advantages. For example, by blocking electromigration of metal components from a conductive feature 158 into the dielectric layer 156, metal leakage is reduced. As a result, TDDB is improved. The RDL 154 may be utilized in any packaging structure, such as integrated fan out (InFO) structure, wafer level packaging (WLP) structure, package on package (PoP) structure, chip-on-wafer-on-substrate (CoWoS) structure, system-on-integrated-chips (SoIC) structure, stacking memory devices structure, or other suitable packaging structures.

An embodiment is a semiconductor device structure. The structure includes a semiconductor die and an RDL disposed over the semiconductor die. The RDL includes a first dielectric layer, a second dielectric layer disposed over the first dielectric layer, and a conductive feature. The conductive feature includes a first portion disposed in the first dielectric layer and a second portion disposed in the second dielectric layer. The RDL further includes a first functional layer disposed between the first dielectric layer and the first portion of the conductive feature and a first n-type insulating layer disposed between the first functional layer and the first portion of the conductive feature. The first n-type insulating layer has a higher concentration of negative ions than the first functional layer.

Another embodiment is a semiconductor device structure. The structure includes a semiconductor die and an RDL disposed over the semiconductor die. The RDL includes a first dielectric layer, a first functional layer disposed adjacent a sidewall of the first dielectric layer, a first n-type insulating layer disposed between the sidewall of the first dielectric layer and the first functional layer, an adhesion layer disposed on the first dielectric layer and adjacent the first functional layer, a first conductive feature disposed adjacent the adhesion layer, and a second dielectric layer disposed over the first conductive feature.

A further embodiment is a method. The method includes placing a semiconductor die over a carrier, forming a molding material around the semiconductor die, and forming an RDL over the semiconductor die. The forming of the RDL includes depositing a first dielectric layer over the semiconductor die, forming an opening in the first dielectric layer, and selectively depositing a first functional layer on a sidewall of the first dielectric layer in the opening. A bonding of the first functional layer and the first dielectric layer forms a first n-type insulating layer between the first functional layer and the first dielectric layer. The forming of the RDL further includes depositing an adhesion layer on the first dielectric layer and the first functional layer, forming a conductive feature in the opening and over a first portion of the adhesion layer, and depositing a second functional layer on a second portion of the adhesion layer and over the conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A packaging structure, comprising:
a semiconductor die; and
a redistribution layer (RDL) disposed over the semiconductor die, wherein the RDL comprises:
a first dielectric layer;
a second dielectric layer disposed over the first dielectric layer;
a conductive feature, wherein the conductive feature comprises a first portion disposed in the first dielectric layer and a second portion disposed in the second dielectric layer;
a first functional layer disposed between the first dielectric layer and the first portion of the conductive feature; and
a first n-type insulating layer disposed between the first functional layer and the first portion of the conductive feature, wherein the first n-type insulating layer has a higher concentration of negative ions than the first functional layer.

2. The packaging structure of claim 1, wherein the first functional layer comprises AlN or TiAlN.

3. The packaging structure of claim 2, wherein the first dielectric layer comprises a polymer.

4. The packaging structure of claim 3, wherein the polymer is polyimide.

5. The packaging structure of claim 1, further comprising a second functional layer disposed between the second dielectric layer and the second portion of the conductive feature.

6. The packaging structure of claim 5, further comprising a second n-type insulating layer disposed between the second functional layer and the second dielectric layer.

7. The packaging structure of claim 5, wherein the second functional layer is disposed on and in contact with the first functional layer.

8. The packaging structure of claim 5, wherein a ratio of a thickness of the second portion of the conductive feature to a thickness of the second functional layer ranges from about 800 to about 2500.

9. The packaging structure of claim 5, wherein a ratio of a thickness of the first dielectric layer to a thickness of the second functional layer ranges from about 1000 to about 4000.

10. A packaging structure, comprising:
a semiconductor die; and
a redistribution layer (RDL) disposed over the semiconductor die, wherein the RDL comprises:
a first dielectric layer;
a first functional layer disposed adjacent a sidewall of the first dielectric layer;
a first n-type insulating layer disposed between the sidewall of the first dielectric layer and the first functional layer;
an adhesion layer disposed on the first dielectric layer and adjacent the first functional layer;
a first conductive feature disposed adjacent the adhesion layer; and
a second dielectric layer disposed over the first conductive feature.

11. The packaging structure of claim 10, wherein the first dielectric layer comprises a polymer, the first functional layer comprises AlN or TiAlN, and the adhesion layer comprises beta-Si₃N₄.

12. The packaging structure of claim 10, wherein the first dielectric layer, the first functional layer, the first n-type insulating layer, and the first conductive feature are in contact with a top surface of a second conductive feature.

13. The packaging structure of claim 10, further comprising a second functional layer in contact with the adhesion layer and the conductive feature, wherein the second dielectric layer is disposed over the second functional layer.

14. The packaging structure of claim 13, further comprising a second n-type insulating layer disposed between the second functional layer and the second dielectric layer.

15. The packaging structure of claim 10, wherein the semiconductor die comprises an interconnect structure and an aluminum pad disposed on the interconnect structure, wherein the RDL is disposed over the aluminum pad.

16. A method for forming a packaging structure, comprising:
placing a semiconductor die over a carrier;
forming a molding material around the semiconductor die;
forming a redistribution layer (RDL) over the semiconductor die, comprising:
depositing a first dielectric layer over the semiconductor die;
forming an opening in the first dielectric layer;
selectively depositing a first functional layer on a sidewall of the first dielectric layer in the opening, wherein a bonding of the first functional layer and the first dielectric layer forms a first n-type insulating layer between the first functional layer and the first dielectric layer;
depositing an adhesion layer on the first dielectric layer and the first functional layer;
forming a conductive feature in the opening and over a first portion of the adhesion layer; and
depositing a second functional layer on a second portion of the adhesion layer and over the conductive feature.

17. The method of claim 16, further comprising depositing a second dielectric layer on the second functional layer, wherein a bonding of the second dielectric layer and the second functional layer forms a second n-type insulating layer.

18. The method of claim 16, wherein the first functional layer and the adhesion layer are conformal layers.

19. The method of claim 16, wherein a top surface of the first dielectric layer and a top surface of the first functional layer are coplanar prior to the depositing of the adhesion layer.

20. The method of claim 16, wherein the adhesion layer is deposited in the opening, and the conductive feature is formed on the adhesion layer.
